(19) United States
(12) Patent Application Publication
(10) Pub. No.: US 2025/0070774 A1
(43) Pub. Date: Feb. 27, 2025

(54) GATE DRIVE UNIT

(71) Applicant: Mitsubishi Electric Corporation, Tokyo (JP)

(72) Inventors: Takashi WATANABE, Fukuoka-shi (JP); Shohei SANO, Fukuoka-shi (JP); Motoki IMANISHI, Tokyo (JP); Shota UENO, Fukuoka-shi (JP)

(73) Assignee: Mitsubishi Electric Corporation, Tokyo (JP)

(21) Appl. No.: 18/766,624

(22) Filed: Jul. 8, 2024

(30) Foreign Application Priority Data
Aug. 22, 2023 (JP) 2023-134518

(51) Int. Cl. H03K 17/567

(52) U.S. Cl. CPC H03K 17/567

(57) ABSTRACT

The Vce detection circuit detects a rise of an inter-electrode voltage between a positive electrode and a negative electrode when the semiconductor switching element is being turned off. The drive circuit is configured to regulate a time to lower the gate drive capability from a first drive capability to a second drive capability based on a detection result of the Vce detection circuit during the turn-off operation of the semiconductor switching element.

### CROSS REFERENCE TO RELATED APPLICATIONS

This non-provisional application is based on Japanese Patent Application No. 2023-134518 filed on Aug. 22, 2023 with the Japan Patent Office, the entire contents of which are hereby incorporated by reference.

### BACKGROUND OF THE INVENTION

### Field of the Invention

The present disclosure relates to a gate drive unit for a semiconductor switching element.

### Description of the Background Art

As an example of a gate drive unit that drives and controls a gate-drive semiconductor switching element, WO 2022/050032 (hereinafter referred to as PTL 1) discloses a gate drive unit that switches a gate drive current in two stages during a turn-off operation.

The gate drive unit disclosed in PTL 1 is configured to switch the gate sink capability by discharging the gate with a first gate drive current from the start of a turn-off operation, and discharging the gate with a second gate drive current which is smaller than the first gate drive current when a delay time Td has elapsed from the start of the turn-off operation. Further, the delay time Td is adjusted by using a surge voltage which is detected as a peak value of a drain voltage during each turn-off operation.

Japanese Patent Application Laid-Open No. 2021-93676 (hereinafter referred to as PTL 2) discloses a semiconductor gate drive unit that can detect a voltage abnormality (unsaturation state) when a semiconductor switching element is being turned on while ensuring insulation.

### SUMMARY OF THE INVENTION

However, according to the gate drive unit disclosed in PTL 1, in order to cope with a variation in the threshold voltage of the semiconductor switching element, it is required to adjust a time to switch the sink capability by using the surge voltage in a plurality of turn-off operations before an appropriate time to switch the sink capability is obtained. Therefore, it is a concerned that the surge voltage may become excessively large if the initial value of the delay time before the adjustment is too short. On the other hand, if the initial value of the delay time is set to the safety side so as to lower the surge voltage, it is a concerned that the switching loss may become large until the delay time is adjusted appropriately.

The present disclosure has been made to solve such a problem, and an object of the present disclosure is to provide a gate drive unit capable of appropriately controlling a gate drive capability of a semiconductor switching element when it is being turned off so as to suppress a switching loss and a surge voltage.

According to one aspect of the disclosure, a gate drive unit for a semiconductor switching element is provided. The gate drive unit includes a voltage detection circuit and a drive circuit that drives a gate of the semiconductor switching element. The voltage detection circuit detects a rise of an inter-electrode voltage between a positive electrode and a negative electrode when the semiconductor switching element is being turned off. The drive circuit is configured to regulate a time to lower the gate drive capability from a first drive capability to a second drive capability based on a detection result of the voltage detection circuit during a turn-off operation of the semiconductor switching element.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram illustrating the configuration of a gate drive unit according to a comparative example;

FIG. 2 is a conceptual waveform diagram during a turn-off operation of the gate drive unit according to the comparative example;

FIG. 3 is a conceptual waveform diagram during a turn-off operation when the sink capability is constant;

FIG. 4 is a block diagram illustrating the configuration of a gate drive unit according to a first embodiment;

FIG. 5 is a conceptual waveform diagram during a turn-off operation of the gate drive unit according to the first embodiment;

FIG. 6 is a conceptual circuit diagram illustrating the configuration of a gate drive unit according to a second embodiment;

FIG. 7 is a first conceptual diagram illustrating the operation of the gate drive unit according to the second embodiment;

FIG. 8 is a second conceptual diagram illustrating the operation of the gate drive unit according to the second embodiment;

FIG. 9 is a conceptual circuit diagram illustrating the configuration of a gate drive unit according to a third embodiment;

FIG. 10 is a first conceptual diagram illustrating the operation of the gate drive unit according to the third embodiment;

FIG. 11 is a second conceptual diagram illustrating the operation of the gate drive unit according to the third embodiment;

FIG. 12 is a conceptual circuit diagram illustrating the configuration of a gate drive unit according to a fourth embodiment;

FIG. 13 is a conceptual waveform diagram during a turn-off operation of the gate drive unit according to the fourth embodiment;

FIG. 14 is a conceptual circuit diagram illustrating the configuration of a gate drive unit according to a fifth embodiment;

FIG. 15 is a conceptual waveform diagram during a normal turn-on operation of the gate drive unit according to the fifth embodiment;

FIG. 16 is a conceptual waveform diagram during a turn-on operation in which an unsaturation state occurs in the gate drive unit according to the fifth embodiment;

FIG. 17 is a conceptual circuit diagram illustrating the configuration of a gate drive unit according to a sixth embodiment;

FIG. 18 is a conceptual waveform diagram during a normal turn-on operation of the gate drive unit according to the sixth embodiment; and

FIG. 19 is a conceptual waveform diagram during a turn-on operation in which an unsaturation state occurs in the gate drive unit according to the sixth embodiment.

### DESCRIPTION OF THE PREFERRED EMBODIMENTS

Hereinafter, embodiments of the present disclosure will be described in detail with reference to the drawings. It should be noted that in the following description, the same or corresponding parts in the drawings will be denoted by the same reference numerals, and the description thereof will not be repeated.

### First Embodiment

### Configuration and Operation of Comparative Example

First, in order to describe the problem in PTL 1 in detail, a comparative example will be described.

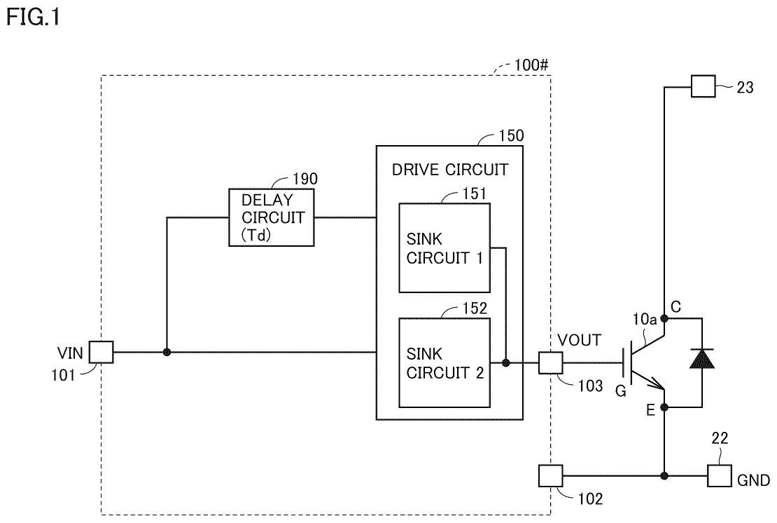

FIG. 1 is a block diagram illustrating the configuration of a gate drive unit 100 #according to a comparative example. The gate drive unit 100 #has a function of switching the sink capability of the gate (gate drive capability), which is equivalent to that described in PTL 1.

As illustrated in FIG. 1, the gate drive unit 100 #has a function of a driving IC (Integrated Circuit) of a semiconductor switching element 10a. The semiconductor switching element 10a is typically constituted by an IGBT (Insulated Gate Bipolar Transistor), and includes a negative electrode (an emitter denoted by E) connected to a low potential node 22, a positive electrode (a collector denoted by C) connected to a high potential node 23, and a gate (a control electrode denoted by G) configured to receive an output voltage VOUT of the gate drive unit 100 #. The semiconductor switching element 10a may be constituted by any other gate-drive semiconductor switching element such as a MOS-FET (Metal Oxide Semiconductor Field Effect Transistor).

In the present embodiment, the low potential node 22 is connected to GND (ground potential), and the potential of the high potential node 23 changes according to the on/off state of the semiconductor switching element 10a, but the low potential node 22 and the high potential node 23 may be connected to any destination.

The gate drive unit 100 #includes a signal input terminal 101, a reference potential terminal 102, an output terminal 103, a drive circuit 150, and a delay circuit 190.

A control signal VIN of the semiconductor switching element 10a is input to the signal input terminal 101. The control signal VIN is a binary signal, and is set to a high level (hereinafter referred to as “H level”) during an ON period of the semiconductor switching element 10a, and is set to a low level (hereinafter referred to as “L level”) during an OFF period of the semiconductor switching element 10a. The reference potential terminal 102 is electrically connected to a negative electrode of the semiconductor switching element 10a. The output terminal 103 is electrically connected to a gate (control electrode) of the semiconductor switching element 10a. Thus, the gate voltage with respect to the negative electrode of the semiconductor switching element 10a, i.e., the gate-emitter voltage (hereinafter, also simply referred to as “gate voltage”) Vge is controlled by the output voltage VOUT of the gate drive unit 100 #.

The gate drive unit 100 #turns on the semiconductor switching element 10a by setting the output voltage VOUT to a positive voltage Vcc during the H level period of the control signal VIN, and turns off the semiconductor switching element 10a by setting the output voltage VOUT to a reference potential (0 V) during the L level period of the control signal VIN.

The gate drive unit 100 #turns on or turns off the semiconductor switching element 10a by generating a gate current through the output terminal 103 to change the gate voltage Vge through the output voltage VOUT. The delay circuit 190 outputs a signal with a delay time Td added to the control signal VIN.

The drive circuit 150 includes a sink circuit 151 and a sink circuit 152 for switching the sink capability (gate drive capability) when the semiconductor switching element 10a is being turned off. The sink circuits 151 and 152 are connected in parallel with the output terminal 103, and the ON/OFF of the sink circuits 151 and 152 are individually controlled. The sink circuits 151 and 152 may be constituted by transistors connected in parallel between the output terminal 103 and the reference potential terminal 102, for example.

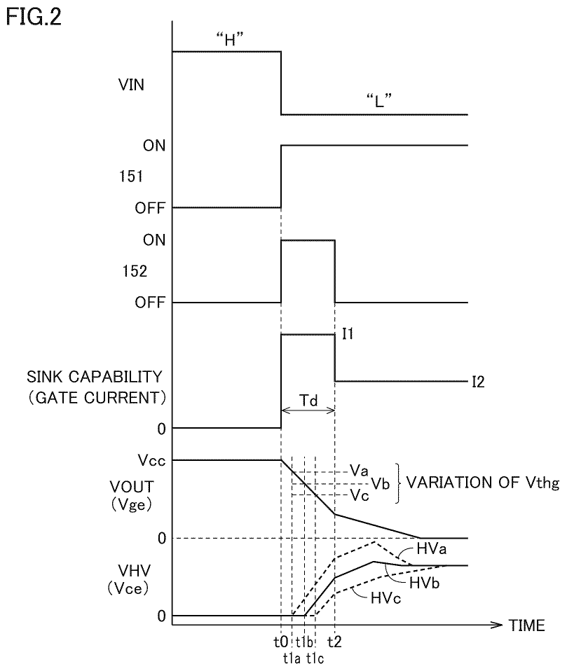

FIG. 2 is a conceptual operation waveform diagram when the semiconductor switching element 10a is being turned off by the gate drive unit 100 #according to the comparative example.

As illustrated in FIG. 2, when the control signal VIN changes from the H level to the L level at time to, the turn-off operation is started. Before time to, the output voltage VOUT of the gate drive unit 100 #is set to the positive voltage Vcc which is higher than a threshold voltage Vthg of the semiconductor switching element 10a, and thereby the semiconductor switching element 10a is in an ON state. In the ON state, a collector-emitter current is generated to flow from the positive electrode to the negative electrode, and a voltage VHV of the high potential node 23, in other words, a collector-emitter voltage Vce which is an “inter-electrode voltage” between the positive electrode and the negative electrode of the semiconductor switching element 10a, is equal to the reference potential (0 V, GND). In each of the following waveform diagrams, 0 V of the output voltage VOUT and the collector-emitter voltage Vce (voltage VHV) corresponds to the potential of the reference potential terminal 102 (the potential of the negative electrode of the semiconductor switching element 10a).

The sink circuits 151 and 152 are turned off during the ON period of the semiconductor switching element 10a, and are turned on at time t0 when the turn-off operation is started. Each of the sink circuits 151 and 152 generates a gate current for discharging the gate of the semiconductor switching element 10a through the output terminal 103.

The sink circuit 151 is turned on during the OFF period of the semiconductor switching element 10a, in other words, during the L level period of the control signal VIN. On the other hand, the sink circuit 152 is turned off at time t2 when the output signal of the delay circuit 190 changes from the H level to the L level. Time t2 is a time at which the delay time Td by the delay circuit 190 has elapsed from time to at which the turn-off operation is started. As a result, the sink capability for discharge by the drive circuit 150 is set to a gate current I1 between time to and time t2 by both of the sink circuits 151 and 152, and is reduced to a gate current I2 (I2<I1) after time t2 by the sink circuit 151 only.

When the turn-off operation is started, the output voltage VOUT decreases from the positive voltage Vcc in response to the discharge by the sink circuits 151 and 152. Since the decrease rate of the output voltage VOUT depends on the gate current, the decrease rate of the output voltage VOUT between time t0 and time t2 is larger than that after time t2. In other words, in the gate drive unit 100 #, the sink capability, i.e., the decrease rate of the output voltage VOUT is switched at time t2 defined by the delay time Td.

Thereafter, when the control signal VIN changes to the H level, the sink circuit 151 is turned off, and thereby the sink capability becomes zero. During the H level period of the control signal VIN, the drive circuit 150 generates a gate current in a direction of charging the output terminal 103 and the gate of the semiconductor switching element 10a.

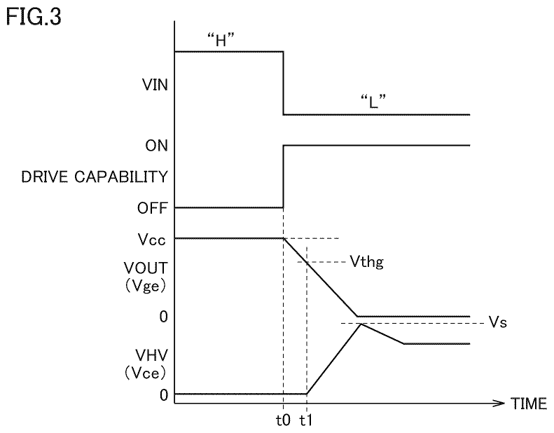

FIG. 3 is a conceptual waveform diagram during a turn-off operation when the sink capability is constant.

With reference to FIG. 3, at time t0, when control signal VIN changes from the H level to the L level as in FIG. 2, the turn-off operation is started. During the turn-off operation of FIG. 3, since the drive circuit 150 discharges the output terminal 103 and the gate of the semiconductor switching element 10a with a constant sink capability (gate current), the output voltage VOUT decreases from the positive voltage Vcc in the ON period to 0 V at a constant rate.

The semiconductor switching element 10a is turned off as the gate voltage Vge decreases from the positive voltage Vcc in accordance with the output voltage VOUT. Specifically, when the gate voltage Vge becomes lower than the threshold voltage Vthg, the collector-emitter voltage Vce begins to rise. After the output voltage VOUT (gate voltage Vge) decreases to 0 V, the semiconductor switching element 10a is completely turned off, and thereby, the collector-emitter current is cut off and the collector-emitter voltage Vce reaches a steady-state value.

The increase rate of the collector-emitter voltage Vce during the turn-off operation depends on the decrease rate of the output voltage VOUT. When the decrease rate of the output voltage VOUT is large, the increase rate of the collector-emitter voltage Vce becomes large, and as a result, a surge voltage Vs, which is the maximum value of the collector-emitter voltage Vce generated during the turn-off operation, becomes high. When the surge voltage becomes excessively high, it may exceed the breakdown voltage of a load to which the semiconductor switching element 10a is connected, thereby damaging the load.

On the other hand, when the decrease rate of the output voltage VOUT is small, the increase rate of the collector-emitter voltage Vce is small, and as a result, the surge voltage Vs becomes low. On the other hand, since the turn-off operation becomes gentle, the time required to complete the turn-off operation becomes longer, and thereby the switching loss becomes greater. As described above, it is known that there is a trade-off relationship in the suppression of the switching loss and the surge voltage with respect to the decrease rate of the output voltage VOUT.

With reference to FIG. 2 again, in the gate drive unit 100 #, the gate current is increased immediately after the start of the turn-off operation between time t0 and time t2 to increase the decrease rate of output voltage VOUT, thereby suppressing the switching loss. On the other hand, the decrease rate of the output voltage VOUT is reduced by decreasing the gate current during the turn-off operation (time t2), thereby suppressing the surge voltage Vs. By providing such a gate current switching function (sink capability), it is possible to suppress both the switching loss and the surge voltage.

On the other hand, there may be a device variation in the threshold voltage Vthg of the semiconductor switching element 10a. FIG. 2 illustrates the waveforms HVa, HVb and HVc of the collector-emitter voltage Vce when Vthg=Va, Vb and Vc, respectively.

When Vthg=Vb, the collector-emitter voltage Vce rises from time tlb. For example, the waveform HVb when Vthg=Vb is the waveform of the collector-emitter voltage Vce when the threshold voltage of the semiconductor switching element 10a is equal to a center value of the specification, and by switching the sink capability at time t2 after the delay time Td has elapsed from the start of the turn-off operation (time t0), it is possible to suppress the surge voltage and the switching loss in a balanced manner.

On the other hand, when the threshold voltage of the semiconductor switching element 10a is within a specific range but higher than the median value, Vthg=Va (Va>Vb) is satisfied, whereby the collector-emitter voltage Vce rises from time tla earlier than time tlb as illustrated by the waveform HVa. On the other hand, since the time to switch the sink capability does not change at time t2, in the waveform HVa, the time to switch the sink capability is delayed with respect to the rise of the collector-emitter voltage Vce in comparison with the waveform HVb. As a result, the surge voltage in the waveform HVa becomes higher than that in the waveform HVb.

On the other hand, when the threshold voltage of the semiconductor switching element 10a is within the specific range but lower than the median value, Vthg=Vc (Vc<Vb) is satisfied, whereby the collector-emitter voltage Vce rises from time t1c later than time t1b as illustrated by the waveform HVc. Therefore, in the waveform HVc, as compared with the waveform HVb, the time to switch the sink capability becomes earlier with respect to the rise of the collector-emitter voltage Vce, which is contrary to the waveform HVa. As a result, in the waveform HVc, the surge voltage becomes smaller than that in the waveform HVb, and it is concerned that the switching loss may become larger.

PTL 1 describes that the delay time Td is sequentially adjusted so that the surge voltage falls within a predetermined voltage range in response to the actual surge voltage during each turn-off operation, but the surge voltage or the switching loss may become large until the delay time Td is set to an appropriate value.

However, since the threshold voltage changes when the temperature of the semiconductor switching element rises, and thereby the appropriate delay time may vary, it is concerned that the switching loss or the surge voltage may become large until the delay time is adjusted appropriately based on the actual surge voltage.

### Configuration and Operation of First Embodiment

Therefore, in the present embodiment, the time to lower the sink capability (gate drive capability) during the turn-off operation is controlled when a rise of the collector-emitter voltage Vce is detected.

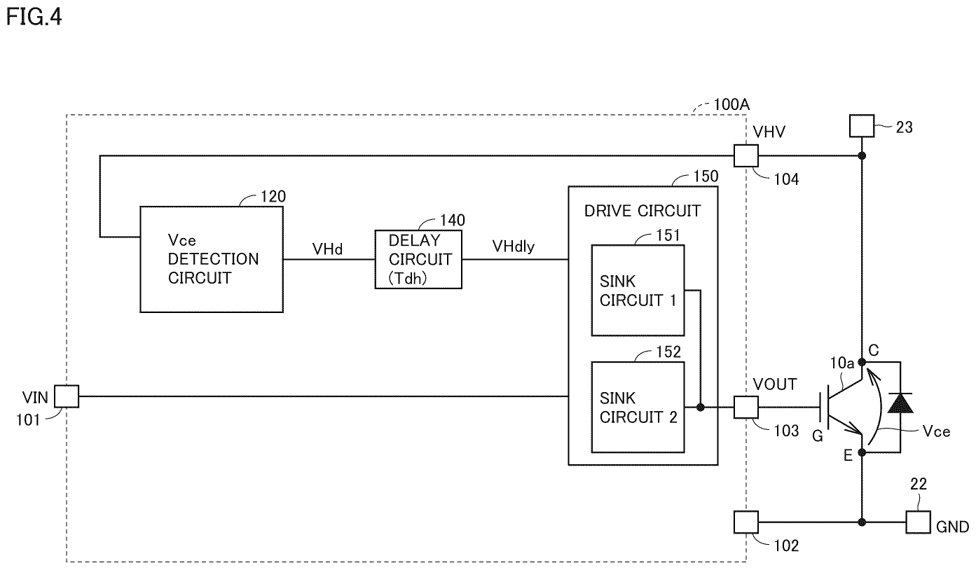

FIG. 4 is a block diagram illustrating the configuration of a gate drive unit 100A according to the first embodiment.

As illustrated in FIG. 4, the gate drive unit 100A includes a signal input terminal 101, a reference potential terminal 102, an output terminal 103 and a drive circuit 150 (which are the same as those in the gate drive unit 100 #according to the comparative example), a voltage detection terminal 104, a Vce detection circuit 120, and a delay circuit 140. The signal input terminal 101, the reference potential terminal 102, the output terminal 103 and the drive circuit 150 are configured in the same manner as in the comparative example (FIG. 1). Accordingly, the drive circuit 150 is configured to switch the sink capability in two stages by using the sink circuits 151 and 152.

The voltage detection terminal 104 is connected to the positive electrode (the collector) of the semiconductor switching element 10a, and is configured to receive a voltage VHV (hereinafter, also referred to as an input voltage VHV) corresponding to the collector-emitter voltage Vce.

The Vce detection circuit 120 is configured to detect a rise of the collector-emitter voltage Vce based on the input voltage VHV. For example, when the input voltage VHV (the collector-emitter voltage Vce) becomes higher than a predetermined determination voltage Vr, the Vce detection circuit 120 changes a detection signal VHd denoting a rise of the collector-emitter voltage Vce from the L level to the H level. The Vce detection circuit 120 corresponds to an example of “a voltage detection circuit”, and the determination voltage Vr corresponds to an example of “a first determination voltage”.

The delay circuit 140 generates an output signal VHdly with a delay time Tdh added to the detection signal VHd from the Vce detection circuit 120. The control signal VIN and the output signal VHdly of the delay circuit 140 are input to the drive circuit 150. The delay circuit 140 may be constituted by, for example, a plurality of (an even number of) inverters (NOT gates) connected in series. The delay time Tdh corresponds to an example of “a first delay time”.

FIG. 5 is a conceptual operation waveform diagram when the semiconductor switching element 10a is being turned off by the gate drive unit 100A according to the first embodiment.

As illustrated in FIG. 5, similar to FIG. 2, when the control signal VIN changes from the H level to the L level at time t0, the turn-off operation is started. Accordingly, the sink circuits 151 and 152 are turned on, and the output terminal 103 and the gate of the semiconductor switching element 10a are discharged by the gate current I1 (sink capability) generated by both of the sink circuits 151 and 152. As a result, the output voltage VOUT decreases according to a decrease rate similar to that between time t0 and time t2 in FIG. 2 to suppress the switching loss.

At time t1, when the gate voltage Vge decreases to the threshold voltage Vthg in response to a decrease of the output voltage VOUT, the collector-emitter voltage Vce begins to rise. At time t3, the collector-emitter voltage Vce rises to the determination voltage Vr of the Vce detection circuit 120. Thereby, the detection signal VHd changes from the L level to the H level.

At time t4 when the delay time Tdh by the delay circuit 140 has elapsed from time t3, the sink circuit 152 is turned off when the output signal VHdly of the delay circuit 140 changes from the L level to the H level. On the other hand, the sink circuit 151 is kept on during the L level period of the control signal VIN.

Thus, after time t4, the gate current (the sink capability) is reduced to I2 in the same manner as that in FIG. 2 after time t2. As a result, the decrease rate of the output voltage VOUT (the gate-emitter voltage Vce) is suppressed so as to lower the surge voltage. The delay time Tdh by the delay circuit 140 may be preliminarily set as a time difference between time t1b and time t2 in the waveform HVb of FIG. 2.

Thus, according to the gate drive unit of the first embodiment, the sink capability (the gate drive capability) of the drive circuit 150 can be switched by an online control in response to the actual rise time of the collector-emitter voltage Vce. As a result, even if the threshold voltage varies due to the device variation or the temperature change of the semiconductor switching element 10a, it is possible to switch the sink capability (the gate drive capability) of the drive circuit 150 at an appropriate time (e.g., equivalent to the waveform HVb in FIG. 2) so as to suppress the surge voltage and the switching loss in a balanced manner. Thus, the effects of manufacturing variation of the semiconductor switching element can be eliminated, and thereby it is possible to stably suppress the surge voltage and the switching loss during the turn-off operation.

### Second Embodiment

In the second embodiment, a preferred example configuration of the Vce detection circuit 120 will be described. The present embodiment illustrates an example circuit configuration that ensures insulation for mounting the Vce detection circuit 120 and the drive circuit 150 on the same IC.

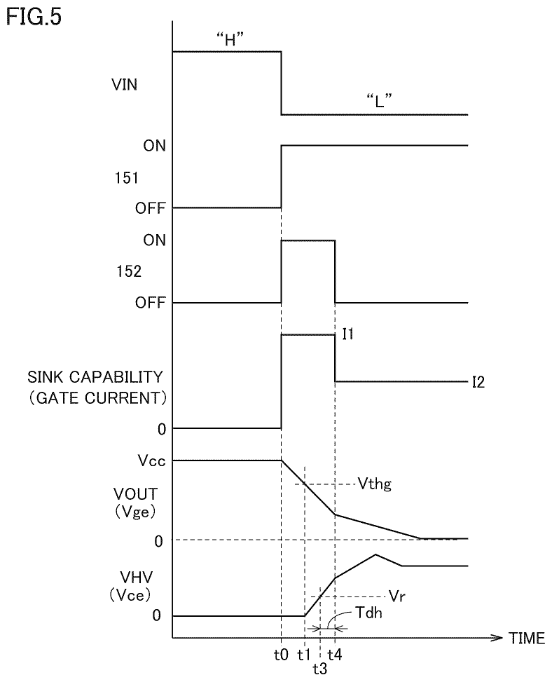

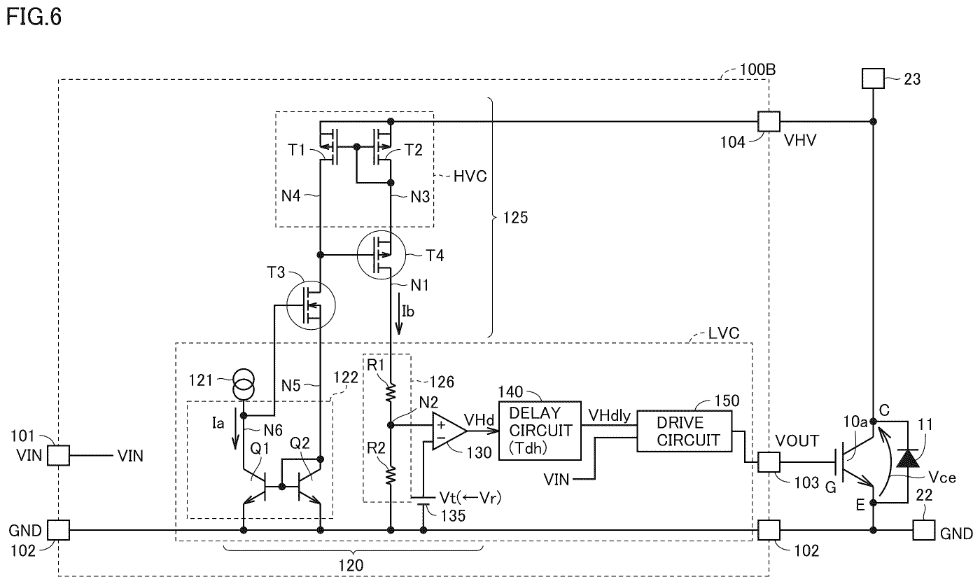

FIG. 6 is a conceptual circuit diagram illustrating the configuration of a gate drive unit 100B according to the second embodiment. The gate drive unit 100B corresponds to the gate drive unit 100A (FIG. 4) in which the internal configuration of the Vce detection circuit 120 is embodied. In other words, the turn-off operation of the gate drive unit 100B is the same as the turn-off operation of the gate drive unit 100A (FIG. 4).

As illustrated in FIG. 6, the Vce detection circuit 120 includes a current source 121, a current mirror circuit 122, a current mirror circuit 125, a voltage divider circuit 126 composed of resistor elements R1 and R2, and a voltage comparator 130.

The current mirror circuit 125 includes P-type transistors T1, T2, and T4, and an N-type transistor T3. Typically, each of the transistors T1, T2 and T4 is a PMOS transistor, and the transistor T3 is an NMOS transistor. The transistor T1 is connected between the voltage detection terminal 104 and the node N4, and the transistor T2 is connected between the voltage detection terminal 104 and the node N3. Thus, the P-type transistors T1 and T2 have a source connected to the positive electrode of the semiconductor switching element 10a through the voltage detection terminal 104.

The transistor T3 is connected between the node N4 and the node N5. The transistor T4 is connected between the node N3 and the node N1. The gates of the transistors T1 and T2 are connected to the node N3 which is a connection node of the transistors T2 and T4. The gate of the transistor T4 is connected to the node N4 which is a connection node of the transistors T1 and T3.

The current mirror circuit 122 includes transistors Q1 and Q2. Each of the transistors Q1 and Q2 is constituted by, for example, an NPN bipolar transistor. The current source 121 outputs a constant current la to the node N6 that is connected to the gate of the transistor T3. The transistor Q1 is electrically connected between the node N6 and the reference potential terminal 102, and the transistor Q2 is electrically connected between the node N5 and the reference potential terminal 102. The bases (control electrodes) of the transistors Q1 and Q2 are connected to the node N5.

Thus, the current mirror circuit 125 corresponds to an example of a “first current mirror circuit”, and constitutes a “current supply circuit” that generates an “output current” to the voltage divider circuit 126. The node N5 is connected to the current source 121 via the current mirror circuit 122, and the current mirror circuit 122 corresponds to an example of a “second current mirror circuit”. The transistors T1 to T4 correspond to a “first transistor” to a “fourth transistor”, respectively.

The voltage comparator 130 outputs the detection signal VHd based on a comparison result between a voltage V+ of the positive input terminal and a voltage V− of the negative input terminal. The detection signal VHd is set to an H level when V+>V−, and is set to an L level when V+≤V−.

Since the positive input terminal of the voltage comparator 130 is connected to the node N2, the voltage V+ is equivalent to the voltage VN2 of the node N2. On the other hand, a voltage source 135 that outputs a determination voltage Vt (which is a DC voltage) is electrically connected between the negative input terminal of the voltage comparator 130 and the reference potential terminal 102 (the negative electrode of the semiconductor switching element 10a).

In the Vce detection circuit 120, the transistors T3 and T4 are connected between a high-voltage circuit HVC constituted by the transistors T1 and T2 and a low-voltage circuit LVC between the nodes N1 and N5 and the reference potential terminal 102. Therefore, the transistors T3 and T4, to which the differential voltage of the high-voltage circuit HVC and the low-voltage circuit LVC is applied between the collector and the emitter, are composed of a PMOS transistor and a NMOS transistor, each of which has a high withstand voltage capable of withstanding the voltage of the positive electrode (collector) of the semiconductor switching element 10a. By using the high-withstand-voltage PMOS transistor and the high-withstand-voltage NMOS transistor to form the gate drive unit 100B according to HVIC (High Voltage Integrated Circuit) technique (PN junction isolation technique), the Vce detection circuit 120 can be fabricated on the same IC with the drive circuit 150.

The current Ia (constant current) of the current source 121 is transmitted, via the current mirror circuit 122, to the P-type transistors T1 and T2 constituting a current mirror. The current Ib flowing through the transistors T2 and T4 changes in accordance with the input voltage VHV (the collector-emitter voltage Vce of the semiconductor switching element 10a) of the voltage detection terminal 104 with the current Ia (constant current) from the current source 121 as an upper limit. The current Ib corresponds to “an output current” supplied to the voltage divider circuit 126. The resistor elements R1 and R2 constituting the voltage divider circuit 126 are connected in series with the current mirror circuit 125 (the transistors T2 and T4) between the voltage detection terminal 104 and the reference potential terminal 102. The resistor elements R1 and R2 are connected in series between the node N1 to which the current Ib from the current mirror circuit 125 is supplied and the reference potential terminal 102 via the node N2. Hereinafter, the resistance values of the resistor elements R1 and R2 are also denoted by R1 and R2.

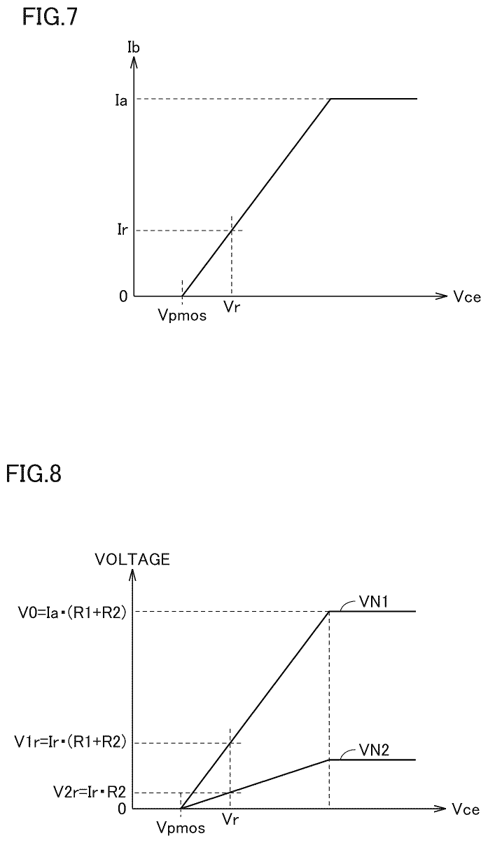

FIGS. 7 and 8 are conceptual diagrams illustrating the operation of the gate drive unit 100B.

FIG. 7 illustrates a characteristic diagram between the current Ib and the collector-emitter voltage Vce.

With reference to FIGS. 2 and 7, since the collector-emitter voltage Vce (the input voltage VHV) is equal to the source voltage of the transistors T1 and T2, the current Ib is not generated in a region where Vce is lower than the threshold voltage Vpmos of the transistors T1 and T2 (Ib=0). When Vce becomes higher than the threshold voltage Vpmos, the current Ib is generated. The current Ib increases as Vce rises, and saturates at the current Ia (constant current) from the current source 121.

FIG. 8 illustrates a characteristic diagram between an input voltage to the voltage comparator 130 and the collector-emitter voltage Vce.

With reference to FIGS. 2 and 8, a voltage VNI equal to the product of the current Ib and the resistance value (R1+R2) described in FIG. 7 is generated at the node N1. A voltage VN2 obtained by dividing the voltage VN1 by R1/(R1+R2) is generated at the node N2. The voltage VN2 is equal to the positive input voltage of the voltage comparator 130. The voltage VN2 is proportional to the current Ib.

In the region where Vce≤Vpmos, VN1=VN2=0; when Vce>Vpmos, the voltages VN1 and VN2 are generated in response to a generation of the current Ib. The voltages VN1 and VN2 increase in proportion to the current Ib as Vce rises, and saturate at the current Ia from the current source 121. The voltage VNI saturates at the voltage V0 which is equal to the product of the current Ia and the resistance value (R1+R2) (V0=Ia·(R1+R2)), and the voltage VN2 saturates at the voltage equal to the product of the current Ia and the resistance value R2.

As illustrated in FIGS. 7 and 8, when the collector-emitter voltage Vce is equal to the determination voltage Vr illustrated in FIG. 5, since the current Ib=Ir (FIG. 7), the voltage VNI is denoted by VN1=V1r=Ir·(R1+R2), and the voltage VN2 is denoted by VN2=V2r=Ir·R2. In other words, the generated current Ib increases to the saturation value (Ia) as the collector-emitter voltage Vce rises in the voltage range including the determination voltage Vr.

Therefore, when the determination voltage (the voltage source 135) input to the negative side of the voltage comparator 130 is denoted by Vt, by setting V2r so that V2r=Vt, the voltage comparator 130 can switch the detection signal VHd to the L level when Vce≤Vr, and switch the detection signal VHd to the H level when Vce>Vr. The determination voltage Vr corresponds to an example of “a first determination voltage”, and the determination voltage Vt corresponds to an example of “a second determination voltage”.

According to the gate drive unit of the second embodiment, the same turn-off operation as that in the first embodiment can be performed by detecting a rise of the collector-emitter voltage Vce during the turn-off operation based on the output voltage of the voltage divider circuit 126 using the output current (Ib) of the current mirror circuit that generates a current in accordance with the collector-emitter voltage Vce.

Thus, it is possible to reduce the resistance value of the voltage divider circuit as compared with the configuration that detects a rise of Vce based on a resistance division voltage of the collector-emitter voltage Vce by simple resistance division. As a result, since the changing speed of the input voltage (positive side) of the voltage comparator 130 in response to the change of Vce is fast, it is possible to improve the detection accuracy of Vce=Vt (time t3) in FIG. 5.

In the example configuration of FIG. 6, the resistor elements R1 and R2 and the current source 121 are not external components but internal components of the IC. Thus, it is possible to improve the accuracy of the voltage (VN2=V2r) of the node N2 for detecting Vce>Vr by paring the resistor elements R1 and R2, paring the transistors T1 and T2 (the current mirror), and paring the transistors Q1 and Q2 (the current mirror circuit 122).

### Third Embodiment

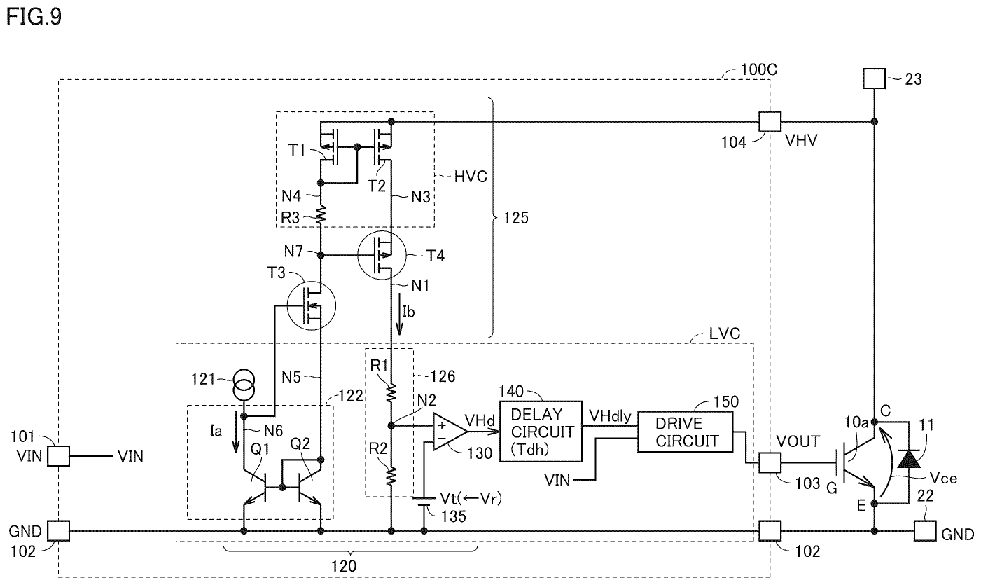

FIG. 9 is a conceptual circuit diagram illustrating the configuration of a gate drive unit 100C according to a third embodiment.

As illustrated in FIG. 9, the gate drive unit 100C is different from the gate drive unit 100B (FIG. 6) in the configuration of the Vce detection circuit 120. Specifically, the gates of the P-type transistors T1 and T2 constituting the current mirror are connected to the node N4 instead of the node N3, and a resistor element R3 is further disposed.

The resistor element R3 is connected between the node N4 and the node N7 corresponding to the drain of the high breakdown voltage NMOS transistor T3. The gate of the high breakdown voltage PMOS transistor T4 is connected to the node N7. The node N7 corresponds to a connection node of the resistor R3 and the transistor T3. In FIG. 9, the node N4 corresponds to a connection node of the transistor T1 and the resistor R3.

The other components of the gate drive unit 100C including the Vce detection circuit 120 are the same as those in FIG. 6 (the gate drive unit 100B), and therefore the detailed description thereof will not be repeated.

In the configuration illustrated in FIG. 6 of the second embodiment, a voltage difference equal to the gate-source voltage of the transistor T2 is present between the input voltage VHV and the voltage of the node N3 in the Vce detection circuit 120. This causes a voltage difference between the node N1 and the input voltage VHV (the collector-emitter voltage Vce).

On the other hand, in the configuration illustrated in FIG. 9, since the gates of the transistors T1 and T2 are connected to the node N4, a current flowing through the nodes N4 and N5 and a current flowing through the nodes N3 and N1 are generated in response to a generation of the current Ia. Thus, the on-resistance (resistance between the drain and the source) of the transistor T2 becomes sufficiently low, and thereby the voltage of the node N3 becomes substantially equal to the input voltage VHV (the collector-emitter voltage Vce).

Further, the gate-source voltage of the transistor T4 (P-type) is ensured by the voltage drop caused by the current in the resistor element R3, which makes it possible to lower the on-resistance of the transistor T4. Thereby, similar to the node N3, the voltage of the node N1 becomes substantially equal to the input voltage VHV (the collector-emitter voltage Vce).

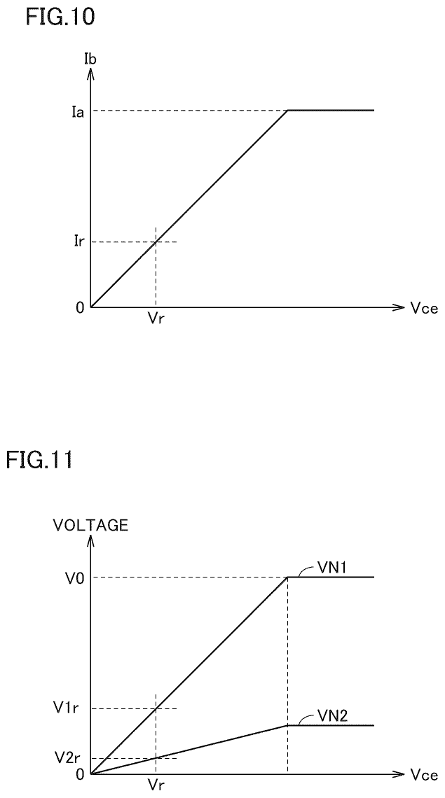

FIGS. 10 and 11 are conceptual diagrams illustrating the operation of the gate drive unit 100C.

Similar to FIG. 7, FIG. 10 illustrates a characteristic diagram between the current Ib and the collector-emitter voltage Vce.

As illustrated in FIG. 10, in the gate drive unit 100C (FIG. 9), when the collector-emitter voltage Vce (the input voltage VHV) is present (Vce>0), the current Ib flowing through the node N1 changes in accordance with the input voltage VHV (the collector-emitter voltage Vce of the semiconductor switching element 10a) of the voltage detection terminal 104 but with the current Ia from the current source 121 as an upper limit. Also in the third embodiment, the generated current Ib increases to the saturation value (Ia) as the collector-emitter voltage Vce rises in the voltage range including the determination voltage Vr.

In FIG. 7 (the second embodiment), if the collector-emitter voltage Vce is not higher than the threshold voltage Vpmos of the transistors T1 and T2, the current Ib is not generated at the node N1. Since the current value Ir at Vce=Vr may be different from the expected value due to changes in Vpmos caused by device variations or the like, there is a concern that an error may occur in detecting the time where the collector-emitter voltage Vce reaches the determination voltage Vt.

On the other hand, in FIG. 10 (the third embodiment), the current value Ir of the current Ib corresponding to Vce=Vr is not influenced by the variation in the threshold voltage Vpmos of the transistors T1 and T2.

Similar to FIG. 8, FIG. 11 illustrates a characteristic diagram between the input voltage to the voltage comparator 130 and the collector-emitter voltage Vce.

Since the voltages VN1 and VN2 are represented by the product of the current Ib and the resistance value (R1+R2) or the resistance value R1, the voltages VN1 and VN2 change in accordance with the collector-emitter voltage Vce similar to the current Ib. By using the current Ib having the characteristic illustrated in FIG. 10 to generate the input voltage (the voltage VN2) of the voltage comparator 130, it is possible to accurately detect the time where the collector-emitter voltage Vce reaches the determination voltage Vr without being affected by the threshold voltage Vpmos of the transistors T1 and T2.

Thus, in the gate drive unit according to the third embodiment, as compared with the gate drive unit according to the second embodiment, it is possible to improve the accuracy of detecting the rise (Vce≥Vr) of the collector-emitter voltage Vce while suppressing the influence of the device variation.

### Fourth Embodiment

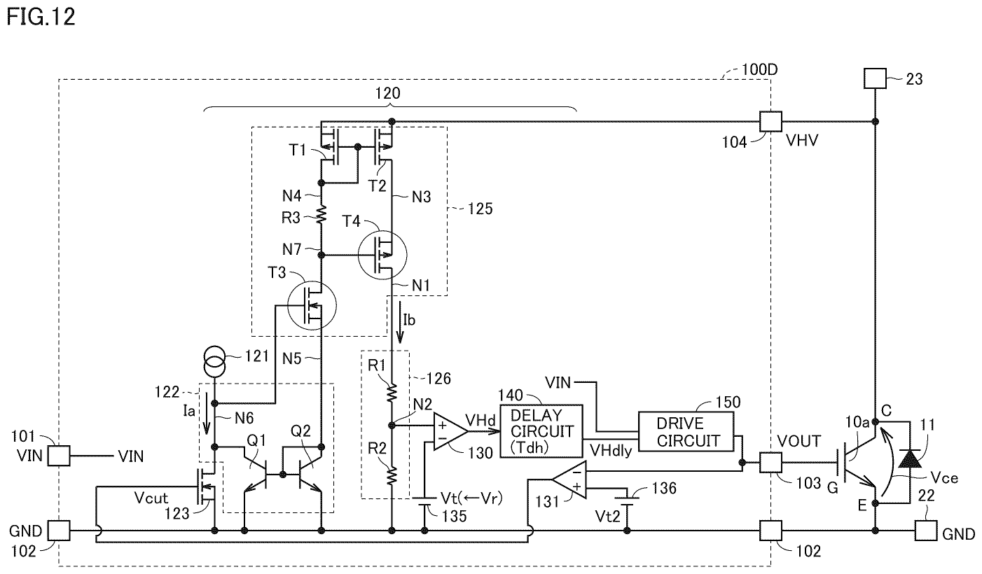

FIG. 12 is a conceptual circuit diagram illustrating the configuration of a gate drive unit 100D according to a fourth embodiment.

As illustrated in FIG. 12, the gate drive unit 100D is different from the gate drive unit 100C (FIG. 9) in that the former further includes a voltage comparator 131 and an N-type transistor 123 which constitute “a current supply stop circuit”.

The voltage comparator 131 outputs a signal based on a comparison result between the output voltage VOUT of the drive circuit 150 and the determination voltage Vt2 from the voltage source 136. The output signal of the voltage comparator 131 is set to the H level when VOUT<Vt2, and is set to the L level when VOUT≥Vt2.

The transistor 123 is connected in parallel with the current mirror circuit 122 (the transistor Q1) between the node N6 and the reference potential terminal 102. In the fourth embodiment, the output signal of the voltage comparator 131 is input to the gate of the transistor 123 as a current stop signal Vcut. The configuration of the other components of the gate drive unit 100D is the same as that of FIG. 9 (the gate drive unit 100C), and therefore the detailed description thereof will not be repeated.

The Vce detection circuit 120 is required to operate when the collector-emitter voltage Vce rises after the turn-off operation is started, and is not required to operate after the rise of the Vce is completed (during the OFF period after the turn-off operation of the semiconductor switching element 10a is completed). Therefore, in order to detect the completion of the turn-off operation of the semiconductor switching element 10a, the determination voltage Vt2 input to the voltage comparator 131 is set to a positive voltage which is close to 0 and lower than the threshold voltage of the semiconductor switching element 10a. The determination voltage Vt2 corresponds to an example of “a third determination voltage”.

Thus, the current stop signal Vcut is set to the L level during the ON period (VIN=H level) of the semiconductor switching element 10a in which the output voltage VOUT is set equal to the positive voltage Vcc. After the start of the turn-off operation, the signal is maintained at the L level until the turn-off operation is completed. Further, the current stop signal Vcut changes to the H level after the completion of the turn-off operation, and is maintained at the H level during the next OFF period of the semiconductor switching element 10a (until the next turn-on operation).

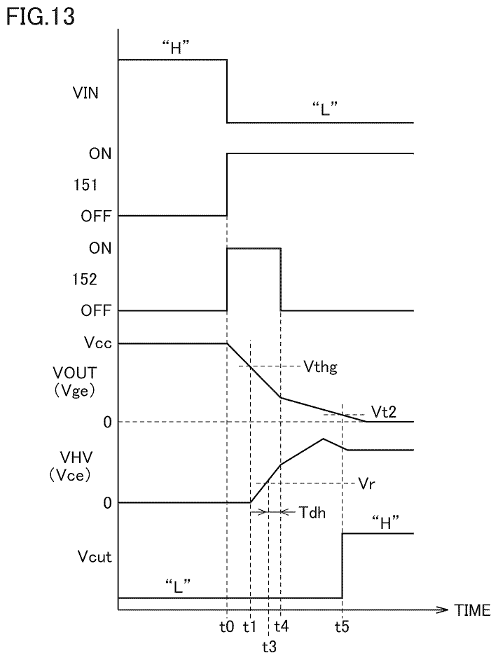

FIG. 13 is a conceptual waveform diagram during a turn-off operation of the gate drive unit according to the fourth embodiment.

The waveforms of the control signal VIN, the sink circuits 151 and 152, the output voltage VOUT, and the input voltage VHV (collector-emitter voltage Vce) in FIG. 13 are the same as those in FIG. 5. FIG. 13 further illustrates a waveform of the current stop signal Vcut in addition to the above waveforms.

As illustrated in FIG. 13, the current stop signal Vcut is maintained at the L level at time to when the turn-off operation is started, but after the output voltage VOUT decreases after the turn-off operation is started, the current stop signal Vcut changes from the L level to the H level at time t5 when VOUT<Vt2.

After time t5, when the control signal VIN changes from the L level to the H level to turn on the semiconductor switching element 10a, the output voltage VOUT rises toward the positive voltage Vcc, and thereby the current stop signal Vcut returns to the L level. During the ON period of the semiconductor switching element 10a, the current stop signal Vcut is maintained at the L level.

During the L level period of the current stop signal Vcut, the current Ia from the current source 121 flows through the transistor Q1, and is input to the current mirror circuit 125 (the transistor T2) via the current mirror circuit 122. Thus, the current Ib is generated in response to the rise of the collector-emitter voltage Vce, and thereby the Vce detection circuit 120 performs the detection operation.

On the other hand, during the H level period of the current stop signal Vcut, the current Ia from the current source 121 bypasses the current mirror circuit 122, flows through the turned-on transistor 132, and is not transmitted to the current mirror circuit 125. As a result, even if the collector-emitter voltage Vce is present, the current mirror circuit 125 cannot generate the current Ib at the node N1. Thus, the Vce detection circuit 120 stops the detection operation.

During the OFF period in which the control signal VIN is maintained at the L level after the completion of the turn-off operation of the semiconductor switching element 10a, since the collector-emitter voltage Vce is present, when the current Ia is supplied to the current mirror circuit 125, the current Ib is continuously supplied to the voltage divider circuit 126. On the other hand, the detection of a time for switching the sink capability at the turn-off is unnecessary during the OFF period after the completion of the turn-off operation of the semiconductor switching element 10a.

Therefore, after the completion of the turn-off operation of the semiconductor switching element 10a, the transistor 132 is turned on to form a current path for the current Ia (the constant current) of the current source 121 to bypass the current mirror circuit 122 (the transistor Q1), and thereby the current Ib in the Vce detection circuit 120 becomes equal to 0 (Ib=0). In other words, the transistor 132 corresponds to an example of “a fifth transistor”, and during the ON period of the transistor 123, the current Ia is not supplied to the current mirror circuit 125, and thereby the current Ib is not generated in the Vce detection circuit 120.

The current la is generated by a low-voltage circuit using a power supply voltage ranging from several volts to a dozen volts. On the other hand, the current Ib is generated by a high voltage (for example, about several hundred volts) of a main circuit which is turned on and off by the semiconductor switching element 10a. Since the power consumption by the current Ib is larger than the power consumption by the current Ia, after the completion of the turn-off operation, the supply of the current Ia is stopped, and thereby the detection operation by the Vce detection circuit 120 is stopped, which makes it possible to reduce the power consumption.

When the semiconductor switching element 10a is turned on after time t5, the output voltage VOUT rises and VOUT>Vt2, and thereby the current la is supplied to the Vce detection circuit 120. However, since Vce=0 during the ON period of the semiconductor switching element 10a, the current Ib is not generated. When the current Ia is supplied, the detection operation of the Vce detection circuit 120 is restarted, preparing for the start of the turn-off operation (time t0) where the control signal VIN changes from the H level to the L level.

As described above, according to the gate drive unit of the fourth embodiment, in addition to the effects of the gate drive unit of the third embodiment, it is possible to reduce the power consumption when the operation of the Vce detection circuit 120 is unnecessary (during the OFF period after the completion of the turn-off operation of the semiconductor switching element 10a).

In the example of FIG. 12, the “current supply stop circuit” constituted by the voltage comparator 131 and the N-type transistor 123 is added to the gate drive unit 100C (FIG. 9) according to the third embodiment, but the “current supply stop circuit” may be added to the gate drive unit 100B (FIG. 6) according to the second embodiment. In this case, the second embodiment and the fourth embodiment may be combined by connecting the transistor 123, to the gate of which the current stop signal Vcut is input, in parallel with the transistor Q1 in the structure illustrated in the figure.

### Fifth Embodiment

In the fifth embodiment, an example configuration in which the Vce detection circuit 120 is also used in the turn-on operation of the semiconductor switching element 10a will be described. Specifically, the Vce detection circuit 120 is used to detect an unsaturation state during the turn-on operation described in PTL 2.

As described in PTL 2, in a semiconductor switching element, an unsaturation state occurs when an overcurrent is generated, and thereby a voltage abnormality in which a voltage between the positive electrode and the negative electrode rises may occur even though the semiconductor switching element is in the ON state. Therefore, it is effective to detect a voltage abnormality (unsaturation state) to avoid the continuous overcurrent state of the semiconductor switching element.

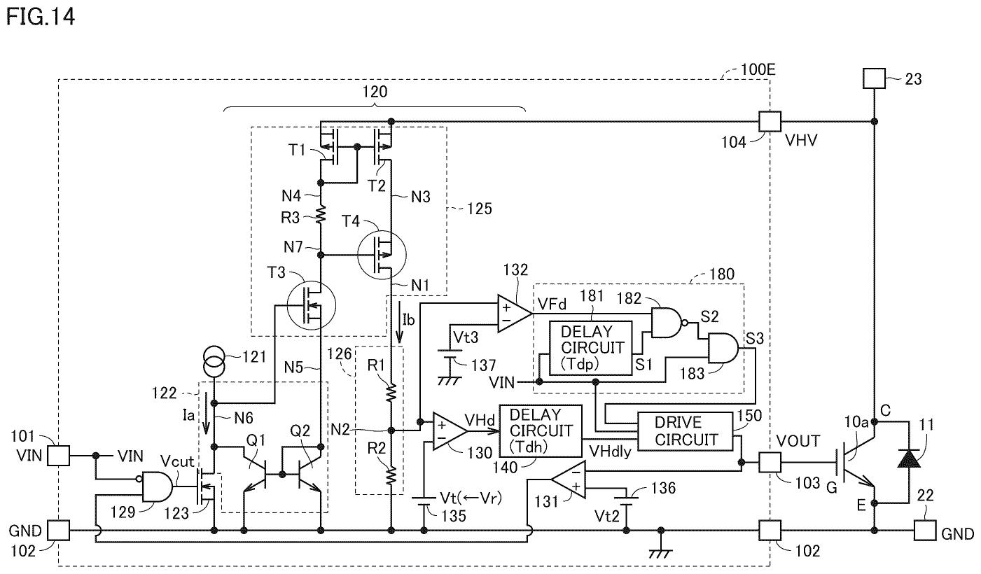

FIG. 14 is a conceptual circuit diagram illustrating the configuration of a gate drive unit 100E according to the fifth embodiment.

As illustrated in FIG. 14, the gate drive unit 100E is different from the gate drive unit 100D (FIG. 12) in that the gate drive unit 100E further includes an AND gate 129 configured to reliably operate the Vce detection circuit 120 during the turn-on operation and a protection circuit 180 configured to operate when an unsaturation state occurs and in that the Vce detection circuit 120 further includes a voltage comparator 132 configured to detect the unsaturation state.

The AND gate 129 inputs an AND operation result of an output signal of the voltage comparator 131 which is the same as that illustrated in FIG. 12 and an inverted signal of the control signal VIN to the gate of the transistor 132 which is the same as that illustrated in FIG. 12 as the current stop signal Vcut. As a result, the current stop signal Vcut is reliably set to the L level during the H level period of the control signal VIN (during the ON period of the semiconductor switching element 10a). Further, since the output signal of the voltage comparator 131 is maintained at the L level during the L level period of the control signal VIN until VOUT≥Vt2, in other words, the current stop signal Vcut is set to the L level until the turn-off operation is completed. Thereafter, when the turn-off is completed, the output signal of the voltage comparator 131 changes to the H level, and the current stop signal Vcut is set to the H level.

The voltage comparator 132 generates a detection signal VFd based on a comparison result between the voltage VN2 of the node N2 of the Vce detection circuit 120 and the determination voltage Vt3 from the voltage source 137. When VN2≤Vt3, the detection signal VFd is set to the L level, and when VN2>Vt3, the detection signal VFd is set to the H level.

The determination voltage Vt3 is set according to the determination voltage Vrdst with respect to the collector-emitter voltage Vce for detecting that the collector-emitter voltage Vce does not decrease because of the occurrence of the unsaturation state at the turn-on time. For example, in the Vce-VN2 characteristic of FIG. 11, the determination voltage Vt3 can be set according to the value of the voltage VN2 when Vce=Vrdst. Accordingly, the voltage comparator 132 operates to set the detection signal VFd to the L level when Vce≤Vrdst, and set the detection signal VFd to the H level when Vce>Vrdst. The determination voltage Vrdst corresponds to an example of “a fourth determination voltage”.

The protection circuit 180 includes a delay circuit 181, a NAND gate 182, and an AND gate 183.

The delay circuit 181 outputs a delay signal S1 with a delay time Tdp added to the control signal VIN. The NAND gate 182 outputs a signal S2 based on a NAND operation result between the detection signal VFd from the voltage comparator 132 and the delay signal S1. Similar to the delay circuit 140, the delay circuit 181 may be constituted by connecting a plural number of (an even number of) inverters (NOT gates) in series.

The AND gate 183 outputs a control signal S3 to the drive circuit 150 based on an AND operation result between the control signal VIN that does not pass through the delay circuit 181 and the signal S2. Based on the control signal S3, the drive circuit 150 generates an output voltage VOUT during the turn-on operation, in other words, during the H level period of the control signal VIN.

During the period from the start of the turn-on operation where the control signal VIN changes from the L level to the H level until the delay time Tdp (the delay circuit 181) has elapsed, since the delay signal S1 is maintained at the L level, the signal S2 from the NAND gate 182 is fixed at the H level. Therefore, regardless of the level of the detection signal VFd, the control signal S3 is at the same signal level as the control signal VIN.

After the delay time Tdp has elapsed from the start of the turn-on operation, the signal S2 is set to the H level when the detection signal VFd is at the L level. On the other hand, the signal S2 is set to the L level when the detection signal VFd is at the H level. In this case, even though the control signal VIN is set to the H level, the control signal S3 is set to the L level. Otherwise, the control signal S3 is set to the H level.

When the control signal S3 is set to the L level during the turn-on operation, the drive circuit 150 detects that a “protection signal” is generated, and turns on the sink circuits 151 and 152 to change the output voltage VOUT to 0 V. The configuration of the other components of the gate drive unit 100E is the same as that of FIG. 12 (the gate drive unit 100D), and therefore the detailed description thereof will not be repeated.

FIG. 15 is a conceptual waveform diagram during a normal turn-on operation of the gate drive unit according to the fifth embodiment.

As illustrated in FIG. 15, when the turn-off operation is started by changing the control signal VIN from the H level to the L level at time to, the output voltage VOUT, the input voltage VHV, and the current stop signal Vcut show the same waveforms as those in FIG. 13.

At time t6, the control signal VIN changes from the L level to the H level, and thereby the turn-on operation is started. Accordingly, the drive circuit 150 charges the output terminal 103 and the gate of the semiconductor switching element 10a to raise the output voltage VOUT to a positive voltage Vcc which is higher than the threshold voltage Vthg. Further, the current stop signal Vcut changes from the H level to the L level, and the detection operation by the Vce detection circuit 120 is started.

At time t7, when the output voltage VOUT, i.e., the gate voltage Vge of the semiconductor switching element 10a becomes higher than the threshold voltage Vthg, a current begins to flow between the collector and the emitter, and the input voltage VHV (the collector-emitter voltage Vce) begins to decrease. When the turn-on operation is normally completed, the input voltage VHV (the collector-emitter voltage Vce) becomes substantially equal to 0 V. Therefore, at time t8 when the delay time Tdp (the delay circuit 181) has elapsed from time t6 (the start of the turn-on operation), since the control signal S3 from the protection circuit 180 is at the H level, the drive circuit 150 maintains the output voltage VOUT equal to the positive voltage Vcc.

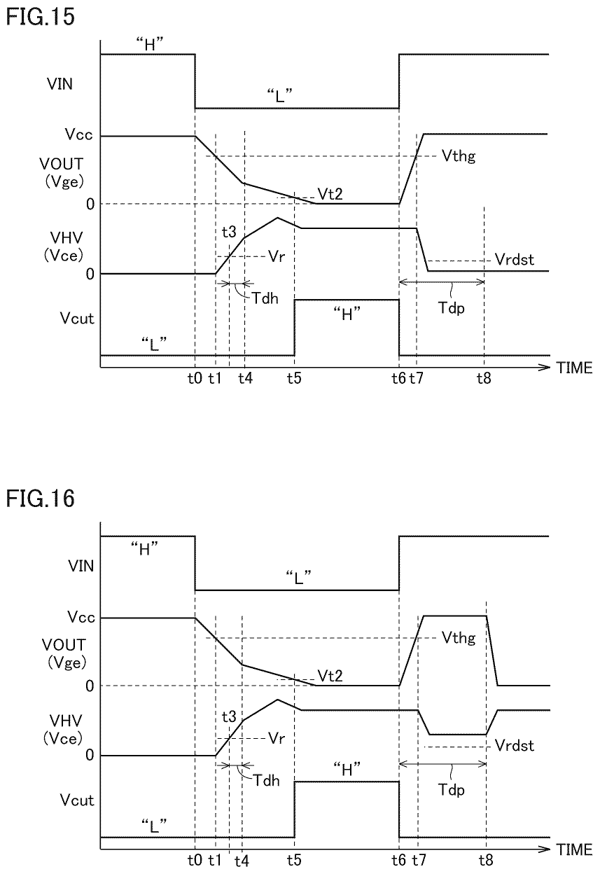

FIG. 16 is a conceptual waveform diagram during a turn-on operation in which the unsaturation state occurs.

Also in FIG. 16, the turn-off operation, i.e., the waveform from time to to time t6 is the same as that in FIG. 15.

In FIG. 16, after the turn-on operation is started at time t6, the input voltage VHV begins to decrease from time t7, but since an unsaturation state occurs in the semiconductor switching element 10a due to an excessive collector-emitter current (overcurrent state), a voltage abnormality occurs, and thereby the input voltage VHV (the collector-emitter voltage Vce) does not decrease as illustrated in FIG. 15 (normal state).

Since Vce>Vrdst is satisfied due to the voltage abnormality, VN2>Vt3 is satisfied in the voltage comparator 132, and thereby the detection signal VFd is set to the H level. Accordingly, at time t8 when the delay time Tdp (the delay circuit 181) has elapsed from time t6 (the start of the turn-on operation), the control signal S3 (FIG. 14) from the protection circuit 180 changes to the L level.

In response, the drive circuit 150 lowers the output voltage VOUT to 0 V, whereby the semiconductor switching element 10a is turned off. Thus, it is possible to realize a protection function of automatically turning off the semiconductor switching element 10a in response to the detection of an unsaturation state at the time of the turn-on operation.

Although FIG. 14 illustrates the configuration which further includes the voltage comparator 132 and the protection circuit 180 (for performing the protection function by detecting an unsaturation state) added to the configuration of the gate drive unit 100D (FIG. 12) according to the fourth embodiment, it is also possible to combine each of the first to third embodiments with the fifth embodiment by adding the voltage comparator 132 and the protection circuit 180 to each of the gate drive units 100A to 100C according to the first to third embodiments.

As described above, according to the gate drive unit of the fifth embodiment, in addition to the effects of the first to fourth embodiments, the Vce detection circuit that is used in the turn-off operation is also used in the turn-on operation to realize the protection function against the overcurrent.

### Sixth Embodiment

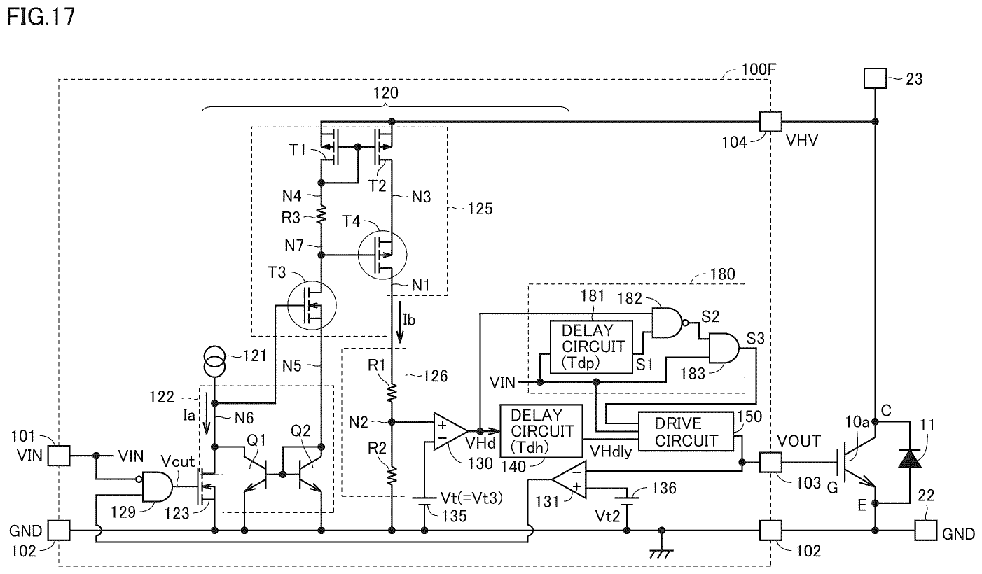

FIG. 17 is a conceptual circuit diagram illustrating the configuration of a gate drive unit 100F according to a sixth embodiment.

As illustrated in FIG. 17, the gate drive unit 100F is different from the gate drive unit 100E (FIG. 14) in that the voltage comparator 132 is not provided. In the sixth embodiment, the determination voltage Vr for detecting a rise of the collector-emitter voltage Vce during the turn-off operation is configured to be equal to the determination voltage Vrdst for detecting an unsaturation state during the turn-on operation.

In the gate drive unit 100F, the detection signal VHd output from the voltage comparator 130 is input to the protection circuit 180. Since the voltage source 135 outputs the determination voltage Vt which is equal to Vt3 (Vt=Vt3), the detection signal VHd during the turn-on operation is the same as the detection signal VFd output from the voltage comparator 132 in FIG. 14.

The configuration of the other components of the gate drive unit 100F is the same as that of FIG. 14 (the gate drive unit 100E), and therefore the detailed description thereof will not be repeated.

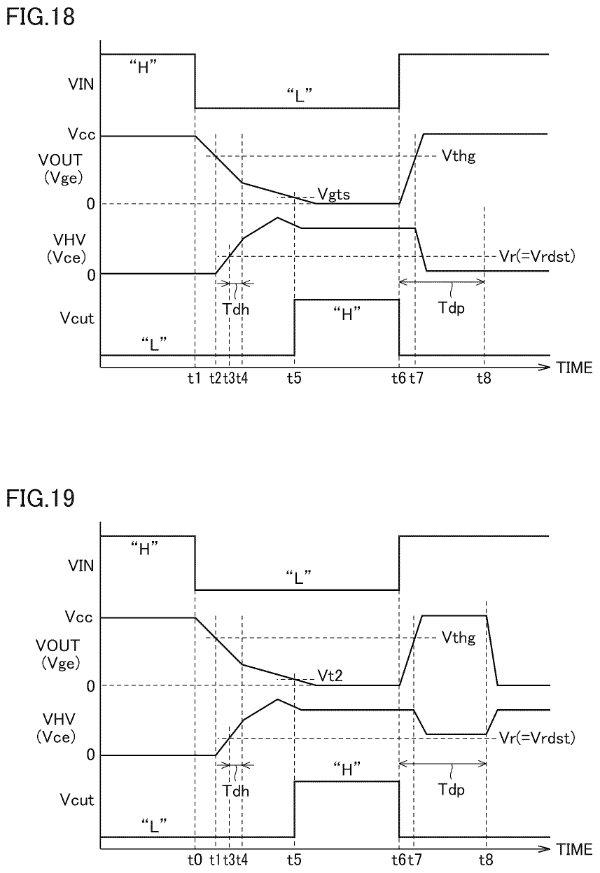

FIG. 18 is a conceptual waveform diagram during a normal turn-on operation of the gate drive unit according to the sixth embodiment.

The waveform diagram of FIG. 18 is the same as the waveform diagram of FIG. 15 except that the determination voltage Vr used in the turn-off operation and the determination voltage Vrdst used in the turn-on operation are equal to each other.

FIG. 19 is a conceptual waveform diagram during a turn-on operation in which an unsaturation state occurs in the gate drive unit according to the sixth embodiment.

The waveform diagram of FIG. 19 is the same as the waveform diagram of FIG. 16 except that the determination voltage Vr used in the turn-off operation and the determination voltage Vrdst used in the turn-on operation are equal to each other.

Since the determination voltage Vr used in the turn-off operation and the determination voltage Vrdst used in the turn-on operation are equal to each other, it is possible to omit the voltage comparator 132 in FIG. 14 and use the voltage comparator 130 that is used in the turn-off operation to realize the protection function against an overcurrent based on the detection of an unsaturation state during the turn-on operation.

However, in the case where the determination voltage Vrdst for detecting the unsaturation state is required to be relatively high (for example, Vrdst is about 50 V) due to the characteristics of the semiconductor switching element 10a, if Vr=Vsdst, there is a concern that the detection of the rise of Vce during the turn-off operation is delayed. Therefore, in such a case, it is preferable to use the configuration of the fifth embodiment (FIG. 14) which includes both the voltage comparator 130 (the determination voltage Vr) and the voltage comparator 132 (the determination voltage Vrdst).

Although FIG. 17 illustrates a configuration which further includes a common voltage comparator 130 (Vr=Vrdst2) and a protection circuit 180 for performing the protection function against an unsaturation state in addition to the gate drive unit 100D (FIG. 12) according to the fourth embodiment, it is possible to combine each of the first to third embodiments and the sixth embodiment by setting Vr=Vrdst2 in the voltage comparator 130 and further including the protection circuit 180 in each of the gate drive units 100A to 100C.

As described above, according to the gate drive unit of the sixth embodiment, in addition to the effects of the first to fourth embodiments, it is possible to realize a protection function against an overcurrent during the turn-on operation while reducing the number of additional circuit elements.

In the present embodiment, an example circuit configuration for generating an output current (current Ib) to the voltage divider circuit 126 in the Vce detection circuit 120 is illustrated in FIG. 6 (the second embodiment) and FIG. 9 (the third embodiment), but the “current supply circuit” that supplies the current Ib may be any circuit configuration as long as the Vce-Ib characteristics illustrated in FIGS. 7 and 10 are realized.

Further, in the present embodiment, it is described that the gate drive units 100A to 100F are mounted on the same IC as the drive circuit 150 and the peripheral circuit such as the Vce detection circuit 120 by the HVIC technology, but the Vce detection circuit 120 may be disposed as an external circuit of the drive circuit 150 which is configured as a drive IC.

In the plurality of embodiments described above, proper combinations of the configurations of the respective embodiments, including combinations not mentioned in the specification, are also originally intended unless they are inconsistent to each other.

It should be understood that the embodiments and the examples disclosed herein have been presented for the purpose of illustration and description but not limited in all aspects. It is intended that the scope of the present invention is not limited to the description above but defined by the scope of the claims and encompasses all modifications equivalent in meaning and scope to the claims.

What is claimed is:

1. A gate drive unit for a semiconductor switching element, the gate drive unit comprising:
a voltage detection circuit to detect a rise of an inter-electrode voltage between a positive electrode and a negative electrode when the semiconductor switching element is being turned off; and
a drive circuit to drive a gate of the semiconductor switching element,
the drive circuit regulating a time to lower a gate drive capability from a first drive capability to a second drive capability based on a detection result of the voltage detection circuit during a turn-off operation of the semiconductor switching element.

2. The gate drive unit according to claim 1, wherein
the voltage detection circuit detects a rise of the inter-electrode voltage when the inter-electrode voltage becomes higher than a predetermined first determination voltage after the start of the turn-off operation of the semiconductor switching element, and
the drive circuit sets the gate drive capability to the first drive capability at the start of the turn-off operation, and lowers the gate drive capability from the first drive capability to the second drive capability at a time when a predetermined first delay time has elapsed after the voltage detection circuit detects the rise of the inter-electrode voltage.

3. The gate drive unit according to claim 2, wherein
the voltage detection circuit includes:
a current supply circuit and a voltage divider circuit connected in series between the positive electrode and the negative electrode; and
a voltage comparator to output a detection signal indicating a rise of the inter-electrode voltage when an output voltage of the voltage divider circuit is higher than a second determination voltage,
the current supply circuit raises an output current to a saturation value as the inter-electrode voltage rises in a voltage range including the first determination voltage,
the voltage divider circuit generates the output voltage in proportion to the output current of the current supply circuit, and
the second determination voltage is set according to the output voltage generated by the voltage divider circuit based on the output current when the inter-electrode voltage is equal to the first determination voltage.

4. The gate drive unit according to claim 3, wherein
the current supply circuit includes a first current mirror circuit connected between the positive electrode and the voltage divider circuit,
the first current mirror circuit generates the output current according to a current of a node connected via a second current mirror circuit to a current source that outputs a constant current, and
the first current mirror circuit includes a first transistor of p-type and a second transistor of p-type, each of which has a source electrically connected to the positive electrode and a gate being interconnected.

5. The gate drive unit according to claim 4, wherein
the first current mirror circuit includes:
a third transistor of n-type connected between the first transistor and the second current mirror circuit and arranged to allow a current supplied from the current supply circuit to flow therethrough; and
a fourth transistor of p-type connected between the second transistor and the voltage divider circuit,
the gate of the first transistor and the second transistor is connected to a connection node of the second transistor and the fourth transistor, and
a gate of the fourth transistor is connected to a connection node of the first transistor and the third transistor.

6. The gate drive unit according to claim 4, wherein
the first current mirror circuit includes:
a third transistor of n-type connected between the first transistor and the second current mirror circuit and arranged to allow a current supplied from the current supply circuit to flow therethrough;
a resistor element connected between the first transistor and the third transistor; and
a fourth transistor of p-type connected between the second transistor and the voltage divider circuit,
the gate of the first transistor and the second transistor is connected to a connection node of the first transistor and the resistor element, and
a gate of the fourth transistor is connected to a connection node of the resistor element and the third transistor.

7. The gate drive unit according to claim 4, further comprising:
a current supply stop circuit to stop supplying a current from the current source to the first current mirror circuit via the second current mirror circuit during a period from the completion of a turn-off operation of the semiconductor switching element to the start of a next turn-on operation of the semiconductor switching element.

8. The gate drive unit according to claim 5, further comprising:
a current supply stop circuit to stop supplying a current from the current source to the first current mirror circuit via the second current mirror circuit during a period from the completion of a turn-off operation of the semiconductor switching element to the start of a next turn-on operation of the semiconductor switching element, wherein
the current supply stop circuit includes a fifth transistor connected in parallel with the second current mirror circuit to form a path which bypasses the second current mirror circuit and allows the constant current from the current source to flow therethrough, and
the fifth transistor is turned on during a period when an output voltage of the drive circuit is lower than a third determination voltage which is lower than a threshold voltage of the semiconductor switching element.

9. The gate drive unit according to claim 1, wherein
the voltage detection circuit further detects an unsaturation state of the semiconductor switching element based on the inter-electrode voltage when the semiconductor switching element is being turned on, and
the drive circuit drives the gate to turn off the semiconductor switching element when the unsaturation state is detected by the voltage detection circuit during the turn-on operation of the semiconductor switching element.

10. The gate drive unit according to claim 2, wherein
the voltage detection circuit further detects an unsaturation state of the semiconductor switching element when the inter-electrode voltage is not lower than a predetermined fourth determination voltage after the start of the turn-on operation of the semiconductor switching element,
the gate drive unit further includes a protection circuit to generate a protection signal when the unsaturation state is detected by the voltage detection circuit at a time when a predetermined second delay time has elapsed from the start of the turn-on operation, and
the drive circuit drives the gate to turn off the semiconductor switching element when the protection signal is generated by the protection circuit.

11. The gate drive unit according to claim 10, wherein
the first determination voltage and the fourth determination voltage are equal to each other.

12. The gate drive unit according to claim 5, wherein
each of the third transistor and the fourth transistor is fabricated using PN junction isolation technology so as to mount the voltage detection circuit and the drive circuit in the same integrated circuit.
